(19) United States
(12) Patent Application Publication
(10) Pub. No.: US 2003/0210649 A1
(43) Pub. Date: Nov. 13, 2003

(54) Managing network loading by control of retry processing at proximate switches associated with unresponsive targets

(76) Inventor: Andre B. Bondi, Red Bank, NJ (US)

Correspondence Address: DUANE MORRIS, LLP, ATTN: WILLIAM H. MURRAY, ONE LIBERTY PLACE, 1650 MARKET STREET, PHILADELPHIA, PA, 19103-7396, US

(21) Appl. No.: 10/428,580

(22) Filed: May 2, 2003

Related U.S. Application Data
(60) Provisional application No. 60/380,062, filed on May 3, 2002.

(51) Int. Cl. G01R 31/08

(52) U.S. Cl. 370/229; 370/338

(57) ABSTRACT

An apparatus and method control the effects of loading due to retries and backlogged status inquiry polling, by reducing the number of message retry attempts and hence the number of queued messages and/or pending retries that are permitted to be directed to a specified target address on a network, during perceived unresponsiveness of the targeted address node. This selectively throttles messages directed to the targeted address node, while reducing the extent to which the unresponsiveness of the targeted address node can produce congestion in proximate switches attempting to direct messages to the targeted address from other points in the network.

### CROSS REFERENCE TO RELATED APPLICATION

This application claims the priority of U.S. provisional patent application S No. 60/380,062, filed May 3, 2002.

### FIELD OF THE INVENTION

The invention relates to the configuration and operation of communication networks so as to limit the overloading or reduce the likelihood of congestion-related failure that can occur when one or more communicating nodes becomes slow to respond, or indefinitely fails to respond, for example, as a result of loading or the occurrence of a fault. The technique is particularly useful to manage call set-up, for example in connection with a Session Initiation Protocol (“SIP”) signaling scheme or the like, wherein messages preliminary to a transaction invite the initiation of a communication connection that is to be maintained temporarily over the network between two communicating nodes.

According to the inventive technique, switches that are logically close to potentially slow or potentially unresponsive target nodes in a communication hierarchy are configured or controlled to vary the retry scheduling, number of permitted retries, and similar criteria affecting the intensity of retrying, in inverse relation to the detected backlog of messages associated with particular target nodes coupled to a proximate switch. This reduces the duration of transactions, which could be increased by transient events at the target node. The result is to localize potential adverse effects of the congestion control.

### BACKGROUND OF THE INVENTION

Modern voice and data communications networks employ packet switching techniques involving discrete message exchanges between a sending point and a receiving point. The sender and the receiver might be logically close to one another along a data flow path in a tree or hierarchy of communicating nodes, for example a (packet-based) telephone handset (whether mobile or fixed) and the telecommunications carrier's nearby edge switch, or the sender and receiver could have many other nodes between them. The sender and receiver could be coupled over a short distance or a long distance, possibly through numerous intervening switches and/or switches coupling between different enterprises or through intervening servers or devices. Data representing various forms of content moves in the form of discrete packets. These packets are sent over network communication paths that are available to and shared by many users concurrently. Most or all of the potential target nodes are available for communication with at least several other nodes. There is a great deal of variability in the capabilities of communicating nodes and in the level of demand that is applied to any given node at any given time.

According to some communication techniques such as TCP/IP (“Transmission Control Protocol/Internet Protocol”), a logical connection is established between the source of a message and its destination, identifying sender and destination addresses or nodes that may be the terminal points of a message. The logical connection is initiated by request and acknowledgement. Packets are identified so that they can be appropriately routed and re-assembled in the required order at the receiver. Establishing a connection in such a way provides some inherent assurance of successful message transmission because it is possible for the communicating nodes to acknowledge a request to exchange data, to manage the data packets, to determine when reception is complete, to acknowledge and end the transmission, and so forth.

The Session Initiation Protocol (SIP) is a signaling protocol for packet switched communications, particularly Internet conferencing, telephony, presence, events notification, instant messaging and the like. SIP is a protocol intended to manage the establishment and exploitation of logical connections using a minimal set of types of messages. A communication begins with an “invite” signal that is expected to result in an acknowledgement back from the target node. The invite message may fail to arrive at the target node due to traffic conditions, the operational state of intermediate switches and the like. The invite message may not be handled promptly, and the expected acknowledgment may fail to arrive back at the source, for that reason or for the same congestion or operational problems affecting the transmission and handling of the invite message. Either or both of the invite message, and the returning acknowledgment, may be lost or delayed by congestion causing the messages to wait or to overflow and be lost in queuing and transmission buffers en route.

Some latency time is associated with any bidirectional messaging protocol. After sending a message to a target node, such as an invitation to establish a message exchange, the sending unit needs to wait for a response. For example, the sending node may need to wait for an acknowledgement (or perhaps a negative reply) from the target node. This represents a message from the target node to the original sender. Messages that are waiting to be handled (invitations, acknowledgements and message content packets, etc.) are saved for processing. The pending messages are work in progress and accumulate as data in buffers and queues.

To allow for the possibility of different causes of losses of outbound and acknowledgment packets, retransmissions or retries can be scheduled appropriately at the source that is attempting to initiate a communication. The invite message could have been lost due to a chance occurrence affecting only the invite message. Therefore, a first retry might be attempted very soon after the initial try. If a second retry is needed, the possibility of congestion justifies waiting for some time interval before sending another retry. Otherwise, the retry message is likely to simply contribute to further congestion. If still more retries are needed, the inter-retry delay interval can be increased with each attempt. The number of retries may be limited to a predetermined number.

There are various specific possibilities for scheduling follow-up retry messages, normally at progressively longer delay intervals if no response is received from the target, and potentially involving error messages, eventual re-routing of the message or abandonment of the message, scheduling of occasional polling thereafter to determine if the unresponsive target is back on line, etc. Reducing the frequency and intensity of messages to the target is helpful for eliminating pending messages that may not be acknowledged, but also makes it less likely that the target will be placed promptly back into operation when the root of the problem is cleared, whatever it might be.

Retaining messages for several repeated retries with successively longer delay times is not helpful when the target of the retries is likely to be unresponsive for a relatively prolonged period, e.g., because it has failed for whatever reason. By contrast, if the unresponsiveness of the target node is of relatively short duration, e.g., because of a brief spike in traffic demand, immediately discarding newly arrived calls is also not helpful. If the lack of response will shortly be cleared, any retry delay may unnecessarily delay completion of the message. It would be advantageous if suitable arrangements could be made to reduce message loading by reducing retry frequency during periods of unresponsiveness and to increase retry frequency when responsiveness resumes, regardless of the cause of unresponsiveness. This is a problem, because the symptom, namely lack of a timely acknowledgement from the target to the sender, could be due to various different traffic level, backlog and capacity issues, or failure of the target node.

Apparent unresponsiveness of a target node has a number of possible causes. Among these are congestion in the network, heavy demand at the target node that results in processing delay, and operational problems at the target node, for example due to lack of power, component failure or another cause. The congestion that is delaying a response from a target node may not be associated with the target node itself, but instead due to operation of a switch that is in turn coupled to the target node. Congestion may be primarily due to traffic at one or more intermediate switches.

Traffic loading conditions on the network vary over time as changes occur in which of the communicating nodes is active, and the extent of such activity. Inasmuch as traffic to and from a node affects the traffic loading of the switch that is logically nearby in the message path (or multiple nearby switches and paths), the backlog of invitations, acknowledgements, message content packets and other messages affects the switch(es) nearby the target node.

It is possible to manage message traffic, by programmed or otherwise configured operation of the switches, by externally imposed conditions and controls on the switches, by limitations on activities of the sending and receiving nodes, etc. There are costs and benefits to managing traffic in one way or another.

For example, some occurrence (e.g., a news event outside of the network) might result in an unusual increase in the demand for communications with a particular node or group of nodes. The backlog of messages in progress for that node (or group) could increase to the point that further attempted messages are slow or entirely stopped because the available queues and buffers are full.

In a different scenario, the responsiveness of a target node can slow or even stop, for one reason or another. A slow response (or lack of response) at a target node at least delays the time at which a disposition can be made for queued messages as they wait for other messages to be handled. At worst, messages are lost or abandoned. Buffers may become full. New messages may be declined, ignored or lost.

On the sending side, unanswered messages may time out. The sender or an intermediate switch then may attempt to retry the message or otherwise to follow up a communication that is unaccountably delayed. Traffic is increased due to extra message requirement of retries, or perhaps new messages to alternative sources of similar services. If the problem at the target node is the result of receiving too many messages per unit time to effectively process, then such retry messages and the like merely contribute to the backlog. On the other hand, if the backlog at the target node is a brief and transitory event, it may be unnecessary and inappropriate to refrain from retry attempts. Some way is needed to reduce the load on the target node if there is congestion, without contributing to the delay of messages if the congestion is transitory.

Some efforts have been made to deal with network congestion that occurs when a great deal of message traffic is placed on a target node or a set of target nodes. One technique is known as call gapping and is used, for example in telephone calling networks to address the problem of an unusual number of calls being directed to a particular target number, or perhaps to a subset of numbers such as a particular exchange or area code. Such congestion can occur, for example, when weather or disaster conditions generate numerous calls into a particular geographic area. The network operators may determine that the area is distinguishable by a particular exchange or area code number, and block or throttle a percentage of calls into the area so as to reduce congestion.

Call gapping as described, limits congestion by preventing the initiation of calls to the congested target area, generally by blocking every n^{th} call to a target number or exchange or area code, based on the dialing string. This method blocks some potentially problematic calls at their source, i.e., before the calls can enter the network, but also may block calls that could be completed within the capacity of the network.

Although broad in its effect, call gapping has the advantageous result that many of the calls that are blocked have a lower than normal likelihood of completion. Throttling the calls improves the likelihood that the admitted calls will be completed and reduces that extent to which the unlikely-to-succeed calls can contribute to congestion of the network at any level. On the other hand, call gapping may not correspond closely with the cause of the overload (except insofar as congestion may correlate to the gapped calling string), or with the most recent state of the overload. It would be advantageous to focus on the reason for an overload and also to respond based on the present overload conditions instead of a perception of overloading.

Other efforts have been made to deal with congestion of networks of various types. They are generally not particularly suited to multi-service packet switched network calls that may involve multiple targets, multiple call legs or other attributes. Many such calls are more variable and complex than simply dialing and coupling to a remote telephone set. Calls may entail relaying of messages and ancillary calls to be completed to attend to a transaction. For example, a call to a voice system with a voice mail capability may entail ringing a target, switching to a directory server, switching to an alternative target, ancillary calls to a voice mail server, signaling to record messages, playing of prompt messages for the user to take various actions, authentication of the user before permitting access, further switching and services, and so on. It is not possible to know in that situation which of the target nodes might be accessed.

Some overload related disclosures are contained in U.S. Pat. No. 6,469,991—Chuah; U.S. Pat. No. 6,134,216—Gehi et al.; U.S. Pat. No. 6,327,361—Harshavardhana et al.; and U.S. Pat. No. 4,769,810 and U.S. Pat. No. 811—Eckberg et al. For example, Chuah throttles or squelches sources of congestion by identifying sources having a high frame error rate, which is determined by the congestion of uplink and/or downlink buffers, and signaling the offending source to reduce its rate of transmission. Like gapping, such an arrangement advantageously reduces congestion due to messages that are less likely to succeed. The technique is not directed to limiting messages associated with unresponsive targets, or more particularly, messages that may be directed to an unresponsive target along a particular functional leg of a multi-service call that has a number of different functional legs or aspects that each concern one or more addressed target nodes.

In Gehi et al., overload controls are activated when certain measurable parameters suggest that a certain level of network traffic has been reached. The triggering parameters can be the number of backlogged entries in a queue. However, there is no teaching of a control wherein the backlog of pending messages for a particular target address is to be made a parameter of interest that affects messages to that address. Harshavardhana et al. is another example of blocking messages from entering a communication network. A number of rules are proposed, relating to a plurality of types of calls. The two Eckberg patents teach monitoring the rate of message traffic in particular data streams, and tagging packets when the rate exceeds the level for which the respective parties have contracted. The tagged excess-rate packets can be discarded preferentially, thus reducing loading.

It would be desirable to provide a session protocol arrangement in which call initiation signaling is optimally arranged to reduce complexity, and operates in a way that is sensitive to congestion and is self limiting so as to decrease the incidence of unnecessary congestion. It would also be desirable if any throttling or reduction in the rate of calling takes into account the congestion situation at the receiving end of the message. It would further be advantageous if this could be handled in a way that controls the number of follow-up retry, status polling and similar messages that are generated when congestion arises in association with a receiving node address, while also permitting resumption of full service at that node address quickly after the congestion has eased.

### SUMMARY OF THE INVENTION

It is an object of the invention to reduce the backlog associated with an unresponsive addressable node on a network to communication paths that are directly associated with the node and not other paths. It is a further object to limit congestion that occurs at the addressable node and its proximate switch or switches, when the congestion might have any of several different causes.

It is also an object to reduce the extent of congestion that is permitted to accumulate in a proximate switch attempting to address a slow or unresponsive distal node in a network, by varying the number of retry transmissions that will be permitted as a function of localized loading of that node. More particularly, the number of retries permitted from a proximate switch to its slow or unresponsive coupled node is reduced, when wait time for processing, the number of messages queued and pending action, and/or other indications of loading specifically at said unresponsive node, indicate that retry attempts are likely to be unsuccessful or to contribute unduly to the loading.

By responding autonomously to congestion at the proximate switch, which is near the logical terminus of the congested message transmission path, and further by taking steps to ameliorate the load specifically by reducing tolerance at the proximate switch for delay at the coupled node, the invention has the advantageous effect of reducing the tendency for network congestion to spread outwardly into the general network from congested target nodes. The particular level of tolerance or intolerance for delay can be switched between two preset modes, namely reducing the maximum number of permitted retransmissions from a preset higher number to a lower number, when congestion passes a predetermined threshold. Alternatively, the threshold can be adjustable or the higher and lower numbers for permitted retransmissions can be variable. The variation can be a programmed function of the proximate switch or can be a criterion that is imposed by an external controller that signals a data value to the proximate switch to indicate a state of loading or congestion in the overall network.

In a particular application of the invention, it is an object to reduce the traffic in a Session-Initiation-Protocol (SIP) messaging network by reducing the average number of pending entries in the retry queues specifically associated with a given targeted node when that node becomes slow or fails to acknowledge messages, thus reducing the number of pending retry messages that must be cleared if the slow or failing node comes back to a more responsive condition. Even more particularly, this object is applied to a multifunction call control apparatus wherein the progress of a user's call may invoke services selectively, such as directory and voicemail services, playing and recording of stored bit-streams, data modifications, etc., which are commenced by sending “invite” messages to target addressable nodes coupled to the network.

These and other objects are accomplished by an apparatus and method that control the effects of loading due to retries, by reducing the number of queued messages and/or pending retries that are permitted to be directed to a specified target address on a network, during perceived unresponsiveness of the targeted address node. This selectively throttles retransmission messages directed to one or more targeted address nodes, as a function of congestion.

It is an aspect of the invention that calls entering a network are not throttled during congestion conditions, except insofar as such calls may be determined when arriving at the proximate switch to involve a congested target address. The congested state of the targeted node is detected by the backlog of pending messages for the targeted node at a proximate switch coupled to the addressed target node. One or both of the number of backlogged messages and the timing of backlogged messages preferably provides a measure of the level of responsiveness of the target node.

The preferred step taken to ameliorate congestion associated with the target node, as detected in this manner, is to reduce the maximum number of communication attempts for each connection setup that will be permitted to be directed toward that target node in congestion conditions of that target node, and thus to reduce the average number of pending connections. The maximum number of attempts per connection setup preferably is determined autonomously at the proximate switch, which typically is the logical location at which pending messages for the target node are queued and accumulate. In an application in which the proximate switch has plural targetable nodes or subsets of nodes, the congestion conditions of the respective nodes or subsets, and optionally then number of permitted retries, are determined for each.

### BRIEF DESCRIPTION OF THE DRAWINGS

There are shown in the drawings a number of exemplary arrangements to illustrate an implementation of the invention as presently preferred. It should be understood that the arrangement shown in the drawings is a nonlimiting example, and this arrangement or its component parts are capable of some variation within the scope of the invention as defined in the appended claims. In the drawings,

FIG. 1 is an overall block diagram for consideration in discussing the configuration and movement of messages in a network.

FIG. 2 is a graph of a subnet portion wherein a call control apparatus contains the proximate switch and the target nodes can be terminals or function legs for requesting and obtaining data related services.

FIG. 3 is block diagram illustrating pertinent elements of the subnet and call control apparatus.

FIG. 4 is a flowchart illustrating an exemplary process for varying the tolerance at the proximate switch for delay associate with an addressable node, which can be one of many that are addressable by the proximate switch.

FIGS. 5 and 6 are example graphs of discrete event simulations comparing the number of messages (Y axis) over time (X axis) with and without retransmission suppression according to the invention, the traces representing the number of currently unacknowledged calls (diamond dots), cumulative number of abandoned calls (square) and the cumulative number of acknowledged calls (triangle).

### DETAILED DESCRIPTION OF THE PREFERRED EMBODIMENTS

For purposes of this disclosure, it is assumed that an exemplary communication is represented by a “call” to a target node or device that could be at the bottom of a hierarchy of devices that are coupled to a network by switching devices, or could be target nodes at intermediate points in a branching network leading to a device. Insofar as a particular message is concerned, the target node or unit or device can be considered to be the distal or terminal unit along an indefinite call transmission path through the network, from an unknown sending node or device. The nature of the call and the service to be provided by the target node likewise can vary, and the invention is applicable to a broad range of possible network configurations and services.

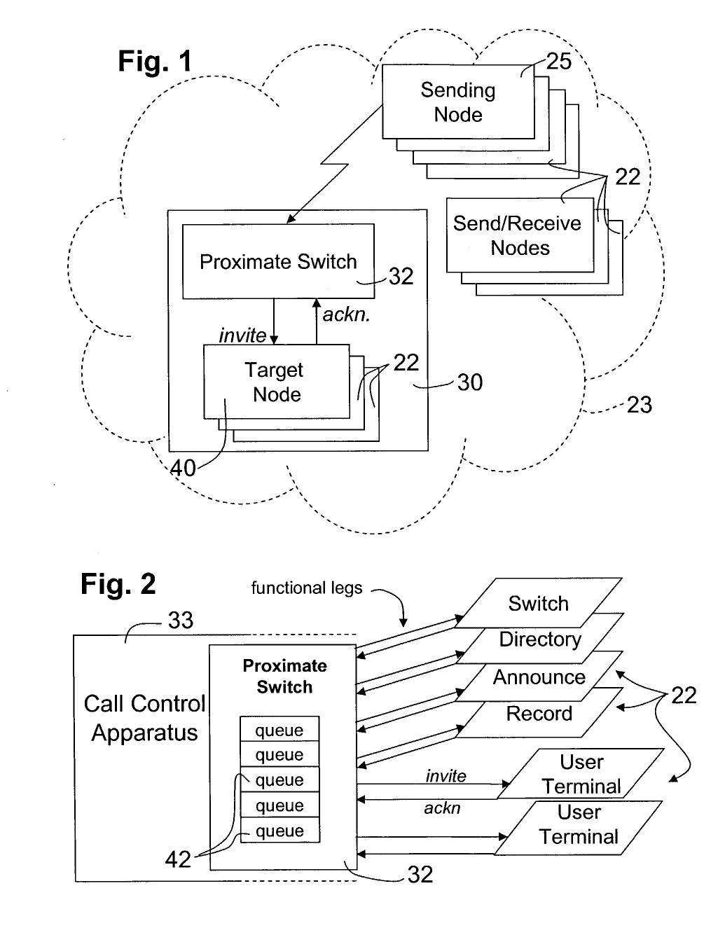

Referring to FIG. 1, the network has numerous nodes 22 that normally are capable of sending or receiving messages for one purpose or another. The nodes 22, shown generally as occupying a network 23, are coupled by communication paths and switches, whereby messages addressed to certain nodes 22 are routed correctly. In order to direct calls to the desired nodes 22, every node 22 is coupled to one or more switches that are proximate to the node in the sense that the switches determine whether messages are to be switched to the node or elsewhere. If two switches are serially coupled to a node, then the switch that is immediately adjacent to the node is relatively more proximate to the node than the next switch proceeding away from the node. However, in a branching network, the latter, or less-proximate switch can be considered the most proximate switch to the subnet comprising the more-proximate switch and the node. Therefore, the term “proximate” when referring to the proximate switch of a target node is not limited only to the immediately proximate switch, and includes the notion of other switches that are higher in a branching or other hierarchy.

In the arrangement shown in FIG. 1, a sending node 25 is directing a message to a target node 40 that is one of several addressable target nodes 22, 40 that are associated as a subnet 30 by virtue of being coupled to a proximate switch 32.

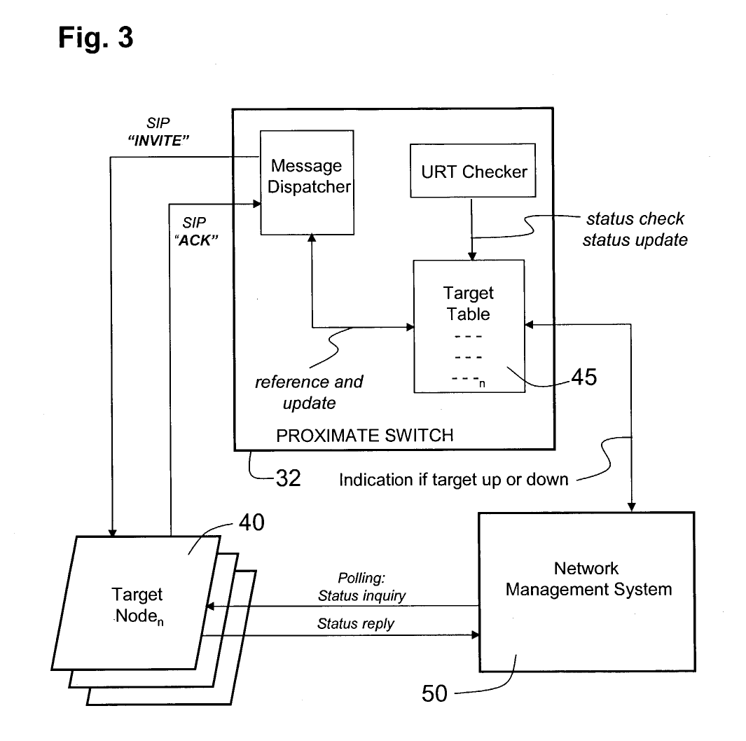

The proximate switch at least gates or switches messages to target node 40 that are intended to be directed to such node 40 by virtue of addressing information that is contained the switched message or in another message that is related to the switched message. This switching or addressing function might be more or less complicated and could include activity of a call control apparatus, shown in FIG. 2, and in more detail in FIG. 3. In connection with the invention, the proximate switch preferably includes the capacity to accumulate messages intended for a target node. If messages for the same node are received more quickly than they are processed, one message waits while another is sent.

The invention is particularly applicable to Session Initiation Protocol or SIP signaling, which is a preferred protocol for versatile internet telephony wherein different sorts of sessions can be established between or among nodes. SIP communication commences when a calling node invites a callee node to participate and the callee node responds in the affirmative. That is, a successful SIP initiation begins with two messages, namely a sent INVITE message from a calling node, followed by a corresponding ACK message sent from the callee to the caller

An INVITE request typically contains a session description, for example according to a standard format such as Session Description Protocol (SDP or RFC 2327) format. The INVITE request provides the called party with information needed to join the session. For multicast sessions, the session description enumerates the media types and formats that are available and allowed to be distributed during that session. For a unicast session, the session description enumerates the media types and formats that the caller is willing to use and where it wishes the media data to be sent. In either case, if the callee wishes to accept the call, it responds to the invitation by returning a similar description listing the media it wishes to use. For a multicast session, the callee should only return a session description if it is unable to receive the media indicated in the caller's description or wants to receive data via unicast. In this way, the specifics of the transaction are negotiated and can commence. The SIP signaling paths and switches need not be the same paths that are used for eventual transfer of content.

In the embodiment shown in FIG. 2, the proximate switch 32 (see FIG. 1) is a component of or an external part associated with a call control apparatus 33 (See FIG. 2). The target node could be a media storage device with record or replay capability, a translating device or various other sorts of devices. The problem of congestion arises when messages for a target node 40 are not processed as quickly as they are sent. This raises issues as to how to handle a situation in which a call, for example commenced with a Session Initiation Protocol “Invite” signal, fails to elicit a response, or at least a prompt response, from the target node.

Apparent unresponsiveness of a target node has a number of possible causes. Among these are congestion in the network, heavy demand at the target node that results in processing delay, and operational problems at the target node, for example due to lack of power, component failure or another cause. These situations can result in a scenario in which the proximate switch has sent several messages to the target node, which have not resulted in reception of an ACK or other reply back at the proximate switch.

One aspect common to the reasons for failure to respond is that of a surge occurring in the demand for network resources, which at least temporarily is not met by the supply. According to the present invention, it is recognized that this demand often is demand specific to the addressed node. Many messages may be sent from various senders (or from the same sender through various switches) to the same addressed target node.

FIG. 2 shows a call control apparatus 33 incorporating or being associated with proximate switch 32, containing a number of message queues 42, including a queue for each of the send/receive targetable nodes 22 coupled to the proximate switch 32. These queues may grow longer or shorter depending on demand, namely messages to be sent to the associated target node 22 and messages that have been sent and are awaiting a reply, etc.

The operation of the proximate switch 32 can be such that there is a limit on the delay during which the proximate switch will wait for an acknowledgement before retrying or perhaps returning to the sender a negative reply on its own. The queues in the proximate switch may also have a maximum permitted capacity due to hardware or software considerations. As a further possible limitation, it is possible that some externally imposed limit may be imposed, for example by a supervisory unit signaling all or a subset of switches in the case of very high traffic, to alter operations in view of the traffic, such as to reduce the rate of signaling or to automatically “gap” calls addressed to a particular group of addressable nodes such as a telephone area code.

According to an aspect of the present invention, a limitation is provided by the programmed operation of the call control apparatus within (or directly associated with) the proximate switch, requiring only locally available information and input. Moreover, the invention provides limitations that can be distinctly different for specific target nodes coupled to the proximate switch, because the limitation is based on the information available regarding the number of entries and/or the response times in the queues of messages for the corresponding addressable target node, as well as the number of messages queued for each target node. This technique does not require supervisory signaling, does not unnecessarily limit traffic that is intended for any target node other than a node that is experiencing undue load (including other target nodes coupled to the same proximate switch 32), and is optimally efficient in TCP/IP switching environments as well as protocols such as SIP that operate therein.

The invention is subject to certain variations and alternatives with respect to the manner of determining when a node is overloaded, and the precise nature of the response. For example, the invention can require limitations when the queue reaches a threshold number of messages or delay. The threshold can be variable for different target nodes or variable as a function of the long term or short term history of operations of the target node. The limitations can be on/off switched limitations or can be proportionate to the extent of the backlog.

In an exemplary embodiment particularly intended for SIP signaling applications, retry transmissions for a particular target node are repressed when the number of queued messages and/or the backlog in response times, reach a threshold that is determined for the target node to represent a problematic overload condition. In this example, such repression is applied simply by reducing the maximum number of retry messages that will be attempted.

Therefore, in this embodiment when the number of unacknowledged calls to a target within a chosen time interval T has exceeded a threshold T1a, and when the number of calls in transition at the proximate switch (the one addressing the target directly) has exceeded some other threshold T2a, the maximum number of SIP call reattempts should be reduced, for example from six to two, until a predetermined time interval T3a after the failure condition abates or until the proximate switch makes a decision to reject all calls for this target, whichever comes first. A decision to reject all calls to this target shall be made when the threshold T1 on the number of unacknowledged calls has been exceeded for a designated time interval t1a and the total number of calls in transition has exceeded T2a for t1a. The failure condition will be deemed to have abated if call acknowledgment resumes, or (if calls have been rejected by the switch or turned off by a Network Management System (NMS)) if a message that the condition has abated comes from the network operations center (NOC) or other designated system or authority. The proposed mechanism is a form of retransmission suppression.

The time interval T is chosen to ensure that this retransmission suppression mechanism is not triggered prematurely if there is a burst of new calls for the target. T should be greater than the length of the intervals between the first and second message transmission attempts, but not so great as to permit saturation of the proximate switch in the event of a sufficiently enduring surge of new calls. If T=0, retransmission suppression will be triggered soon after every burst of T2a calls, including T1a calls destined for the target Since the T2a calls include those for the target, we must have T2a ≧T1a,

If chosen time interval T is too large, the reaction time of the retransmission mechanism will be too long, and there will be less protection of the proximate switch from saturation. Similarly, retransmission suppression may be triggered tardily if T1a and T2a are too large or prematurely if they are too small.

T3a, the time to declare that the unresponsiveness causing congestion has abated, is chosen to allow the proximate switch to purge a substantial part of its backlog before canceling retransmission suppression. If T3a is too short, new calls may cause the memory of the proximate switch to be exhausted.

For the foregoing reasons, T, T1a, T2a and T3 can be administratively tunable to conform to traffic conditions and for optimization in different hardware and software configurations. This provides the designer or operator some leeway to balance countervailing interests such as the extent of protection at the proximate switch, positive or negative operational effects at different levels of processing load, the quickness of reaction to changes in traffic levels and changes in operational conditions, etc.

Thus, the values of the thresholds, and the selection of the maximum number of retransmission tries permitted, are factors that can be varied within the scope of the invention. Also, it will be appreciated that a proportionate response rather than a threshold-based switch in limit values, is also possible. Decisions based on the value of one or more variables, such as the choice of values that will be deemed an overload, and the choice of limiting values to reduce the extent of loading, etc., can be made with due regard for operational and system variables. For example, the determination of queue size and delay could be based on variables that are sampled and compared to historical values (i.e., samples taken at successive times), which requires memory to store the values. Relatively more frequent sampling is possible to render the retransmission limitation more responsive, but that carries a cost in higher processing load. It is possible to select values pragmatically, by statistically analyzing loading data, to balance the costs and benefits of the selections of thresholds and numbers of permitted retransmissions.

In a relatively simple example, the proximate switch is provided capacity to store queued messages sufficient to hold all queued messages that are expected for all the target nodes coupled thereto, for example, over 95% of the range of expected loading conditions. This can involve permitting the legal queue size to be variable within the permitted capacity, whereby certain target nodes can have maximum queues that are larger or smaller than others. Each queue has a separately assigned threshold of number of entries and maximum response delays that if met or exceeded will be logically regarded as a Responsive or Unresponsive state of the associated target node 22. The state of the associated target node 22 can be determined whenever a message is received to be passed to that target node, or the states of the target nodes can be repetitively assessed and stored as flags in a Target Table 45, shown in FIG. 3.

The number of permitted retransmissions then can be based solely on whether the target node State (as listed in the Target Table) is Responsive or Unresponsive. If the State is Responsive, the maximum permitted number is a higher number, for example six. If it is Unresponsive, the maximum permitted number is lower, for example two. The target node State can have more than two possible values (e.g., Responsive, Slow, Unresponsive, Down), representing different levels of responsiveness. Preferably, for example, the target node State that can be recorded in the Target Table 45 has one possible value, e.g., “DOWN,” indicating that no further attempts are to be made. This state can be assumed in the case that the target node has failed to respond to a predetermined number of attempts from the proximate switch, or has failed to respond over a predetermined time, which number or time is sufficient to make a response to a new attempt seem so unlikely as to fail to justify another retransmission attempt.

As also shown in FIG. 3, it is possible to employ a supervisory network manager 50 to periodically poll target nodes that are found to be DOWN. This function is external to the proximate switch and can be considered a management function that applies to many nodes and/or switches and operates at a much slower rate than the invention. The object is to resume the use of nodes that are again able to operate but were previously so unresponsive to be abandoned as DOWN by the proximate switch. Such polling is advantageously done more frequently for target nodes that have been DOWN for a shorter time, and less frequently for those that have been down for a longer time. The frequency of supervisory polling, like the number and/or frequency of retransmissions, is preferably chosen as a function of the likelihood that the target node has revived versus the network and processing load of sending polling or other status inquiry messages.

The Target State of each node coupled to the proximate switch, and subject to monitoring by the call control apparatus thereof, may be determined at various times, based on arithmetic comparisons of the current time with that of the first unacknowledged call and of the number of unacknowledged calls with the threshold. According to a one method for SIP messaging, for example, the determination of the target state could be made every time a SIP INVITE is sent to the associated target node. This has the advantage of involving only the target of the current invite. It has the disadvantage of slowing down every call by incurring the processing cost to consult the target table to determine the Responsive/Unresponsive/Down state and possibly to compare data to thresholds. In an embodiment wherein the responsiveness is encoded and retransmissions are suppressed proportionately, arithmetic computations and comparisons may be needed.

Alternatively, the determination of the target states of all nodes coupled to the proximate switch could be made at regular intervals and assumed to remain valid until determined again for the next interval. The entire table of targets is updated each time, even though one or more of the individual targets may not receive an INVITE during the following interval. This has the advantage of reducing the amount of calculation associated with each SIP call, which is desirable during heavy call loading conditions. It has the disadvantage that spikes of CPU activity are introduced at the intervals, especially when the target table is large, and much of that activity may be wasted on targets that do not receive calls during the subsequent interval. This periodic status update method also limits the reaction time of the control mechanism to as much as the full period of the interval between scans.

When the target of a SIP call fails, the effect of its failure and its detection will occur sooner at the switch which is addressing the target directly (hereafter referred to as the proximate switch) than by the network management system. The reasons for this are as follows.

In a Responsive target node situation, a typical SIP call that fails may be reattempted six times, at progressively longer wait intervals, according to nominal SIP operation. An initial retry may be attempted at half of a full call interval cycle. Until the call is completed, or up to the maximum number of retries, the duration of each successive retry interval can be double that of the previous one to account for the possibility that network traffic is the cause of the inability to complete the call. Assuming that the initial retry interval is 0.5 second (and the expended time on the attempt is negligible) and the maximum number of retries is six, a wholly unsuccessful attempt to complete a call will extend for a duration of 0.5+1+2+4+8+16=31.5 seconds. After 31.5 seconds, the proximate switch can be arranged to conclude that the intended receiving target node is Unresponsive. The proximate switch raises an alarm indicating that the target is unresponsive. This alarm is used in various ways, attempting to prevent the occurrence of futile additional signals to the unresponsive target. Typically, there is some longer period, which itself may be made variable under loading conditions, in which the target node is considered to be out of service and signals to it are not attempted.

Calls may be of a type that can be canceled if not successful in a predetermined time or number of attempts (such as calls for services that can be met by seeking the same service from a different source). Assuming that there is a need for access to the particular target once a call attempt has been made, polling calls can be attempted repetitively by the network management system for a given number of tries or for an indefinite number of tries.

All the calls and/or messages that are in process and aimed at the target, i.e., awaiting a response from a possibly-permanently unresponsive target, can be termed unacknowledged calls and/or messages respectively. The number of unacknowledged calls builds.

The calls made during retry of unacknowledged messages, plus the failed calls and associated reattempts made while the network management system (NMS) is unsuccessfully polling the unresponsive node before declaring its failure, can combine to place a heavy burden on the proximate switch as well as on the network to which it is connected.

If call volume is sufficiently large, the time for a network management system (NMS) to react to the failure of a target by notifying the proximate switch may be long enough to permit saturation of the proximate switch. Typically, the network management system initiates a polling call at five minute intervals to determine whether the target is again responsive. If such a status poll is unacknowledged within ten seconds of a polling call, a subsequent polling call will be made. Preferably the polling calls are also made less and less frequently in the absence of a response, for example continuing after 20, 40, and 80 seconds, for a total attempt duration, for example, of 2.5 minutes. At this point, the NMS may declare the target to be down, and raise an alarm intended to preclude the occurrence of new calls to the unresponsive target. This means that if the call arrival rate at the proximate switch were λ per second, at least 2.5×60×λ=150λ calls could arrive before the proximate switch responds to the failure of the target. Since the network management system (NMS) typically polls nodes every 5 minutes, the reaction time could be as long as 5+2.5=7.5 minutes. In that case, (300+150)λ calls could arrive between the failure of the target and the notification of failure to the proximate switch by the NMS.

In the proximate switch, new calls to the unresponsive “down” target may continue to occur. If calls for the unresponsive target arrive at a rate A per second, the average number of unserved calls will be 31.5λ when failure of the target is declared in the proximate switch. Moreover, under the conventional SIP, calls that have not been abandoned by the caller will be repeatedly reattempted as described above.

The processing demand on the proximate switch increases as each timeout interval passes. If r1 is the first timeout interval and the first call after the target fails arrives at time t0, the effective call arrival rate will double at time t0+r1, because those who arrived in the first r1 seconds will begin reattempting then. At time t0+2r1=t0+r2, the new arrivals will begin competing with those arriving in the first and second intervals beginning at times t0+r1 and t0+r2 respectively. At time t0+3r1=t0+r1+r2, the new arrivals will compete with those calls that arrived in the first, second, and third intervals, and so on.

This chain of events threatens eventually to saturate the proximate switch by consuming all its processing power on retries, new calls that have arrived while retries of earlier calls are in progress. Moreover, the memory allocated to associated queues of uncompleted calls could be exhausted.

There are various possible interconnection patterns possible, but assuming that the proximate switch is higher in some hierarchy than the target, the effect of the load on the proximate switch is to spread the adverse effects of the problem at the target over a larger portion of the network than the target itself. This situation is untenable.

According to an aspect of the invention, a mechanism is provided to mitigate the effect of the overload at the proximate switch. However, this relief is also preferably designed to reduce the time that the calls remain affected as a result of a temporary lapse of responsiveness at the target device. That is, the mechanism reduces loading due to the failure while at the same time improving the extent to which calls can continue to go through if the failure condition abates in a timely manner.

In one embodiment, the invention permits a call to remain in transition for a reduced maximum number of attempts when the number of unacknowledged call attempts exceeds a specified level, we introduce the possibility of completing the call if the failure condition abates while it is in progress.

By reducing the maximum number attempts, we reduce the risk that the switch will be saturated, thus allowing it to recover gracefully from an overload condition caused by a failed target. The average number of calls that would arrive between failure of the target and the reaction of the proximate switch to the failure would be (1+2)λ=3λ calls instead of 31.5 λ calls under the SIP specification. Failed calls are handled as they would be if the usual number of call attempts were permitted.

By solely dropping calls destined for the unresponsive target altogether once its failure has been determined, the switch protects itself from saturation while still being able to process calls destined for other targets.

An important difference between the system of the invention and conventional limitations on call attempts during heavy traffic conditions is that the invention tends to prevent switch overload by limiting the number of reattempts made by calls already in transition involving the unresponsive target. The invention is thus different from the known technique of reducing traffic generally when overloading conditions occur. The invention is based on the recognition that although the proximate switch may be heavily loaded, which is a condition that could be due to a high traffic level throughout the network, that loading may be due to the unresponsiveness of just one or a very small number of target addresses that are very popular for one reason or another.

According to the invention, it is not necessary to discard a proportion of network calls or retry attempts altogether, perhaps without even allowing an attempt to be made to communicate with the target, which may have resumed operations in the meantime. Instead, a call is only discarded when the number of attempts has exceeded a predetermined threshold number, and only if it is addressed to the problem target node through the particular proximate switch.

The invention is seen to provide potential advantages as compared to known traffic control techniques. For instance, call “gapping” is a known technique used in circuit switched networks, which allows only every nth call to be attempted when heavy traffic conditions occur. In telephone switching systems, gapping may be applied to an entire area code (for example, to prevent saturation of local circuits in an area affected by an emergency). Call gapping may be applied to a particular telephone number (such as a toll free number that is suddenly very popular, e.g., because something has just been promoted in a TV commercial). Call gapping prevents the initiation of calls to the number (or area code, etc.) from being admitted to the network in the first place. The system of the invention allows calls to be admitted as long as there is a possibility that the affected target of the call will be responsive shortly.

Bandwidth management is used in high-speed packet-switched networks to throttle the rate at which messages are admitted to the network altogether. Throttling can be applied circuit by circuit, or area by area. It is usually applied connection by connection. Bandwidth management usually acts at the source or the network edge to prevent network overloading by limiting the admission rate to a predetermined number of protocol data units per unit of time. Bandwidth management is discussed in U.S. Pat. Nos. 4,769,810 and 4,769,811 to A. Eckberg (Jr.) and D. Lucantoni.

It is an aspect of the invention that unlike many overload controls that throttle all calls passing through a designated switch, or perhaps all calls in the event of congestion, the invention only throttles calls to one or more specific destination IP addresses, and to accomplish such throttling uses information that is available at a proximate switch that is at least logically close in the signal path to the potentially unresponsive target node, and thus is sensitive and most able to immediately respond to variations in loading of the target node.

Overload controls are usually applied to the network in response to network loading as perceived from the state of a saturated network element. The proposed mechanism acts when one or more specific network elements is out of action or otherwise transiently unresponsive, in a way that allows calls not involving the affected element(s) to be handled normally. This prevents unnecessary processing and optimally preserves the availability of the network capacity for calls that are not involved in the traffic jam. If the malfunctioning target is itself a focus of heavy traffic, logically reducing the capacity of feeder routes into the jam has been surprisingly found actually to reduce the total processing time and resources that are involved in trying to reach the point of the jam. By preventing overload in a way that also reduces the amount of protocol processing associated with it, congestion associated with a transient unresponsive state is relieved more quickly than one in which a great deal of retry and polling processing is permitted to build up as congestion effectively surrounds the point of the traffic jam.

Various overload control mechanisms can be arranged to come into play when resource utilization (e.g., CPU utilization) exceeds a certain high threshold. By contrast, the proposed control mechanism comes into play when the unresponsiveness of a target network element is indicated by the presence of a large number of unacknowledged interactions, and tends to produce benefits by reduction of congestion, well before a network management system would declare it to be down, and well before problematic congestion in the form of a growing number of unacknowledged calls occurs within the proximate switch.

The quantitative decision criteria can be refined by basing them on moving averages of the observed counts of call reattempts and of the observed numbers of calls in transition for the target IP address and overall. This will smooth the effect of fluctuations in call volumes and the numbers of calls present destined for the target. Moving averages (and hence the recent historical data to compute them) need only be maintained for targets for which calls have timed out.

U.S. Pat. No. 5,710,885—Bondi, teaches a data structure dealing with unresponsive targets. The use of moving averages in load controls is taught in U.S. Pat. No. 6,134,216—Gehi et al., entitled Integrated overload control for overload control for distributed real time systems. See also U.S. Pat. No. 6,469,991—Chuah. These patents are incorporated for their overload control teachings. However the prior art fails to disclose how or why loading is controlled by application of any similar teachings to the proximate switch of a network with potentially unresponsive target nodes, such as an SIP messaging network.

In an exemplary embodiment, the invention is implemented using a data structure in the form of a Target Table that tracks whether target addresses are unresponsive or responsive, with counters containing the number of calls in transition and the number of active calls. The table preferably is organized by IP address and accompanied by an ordered data structure for indexing purposes. The data structure may be a hash or a search tree whose keys are IP addresses and whose information fields are pointers to rows in the Target Table. Such a table preferably resides in every proximate switch to track those targets that are accessible from that proximate switch. However it is also possible to provide a network wherein only certain proximate switches are so equipped.

For the sake of illustration, we mark the table as unresponsive if T1a=T2a=2 for reaction time T=5 seconds or more.

Call Counters

| Number of Calls | Number of |
|---|---|
| in Transition | Active Calls |
| 10 | 24 |
| Current Time | 15:32:05 |

| | Target State | Number of | Time of first | Number of | |
|---|---|---|---|---|---|
| Target Name/ | (responsive, unresponsive, | unacknowledged | unacknowledged | calls in | Number of |
| IP Address | reject) | calls | call | transition | active calls |
| A_Responsive_Server | Responsive | 0 | −1 | 2 | 19 |
| An_UnresponsiveServer | Unresponsive | 4 | 15:30:35 | 4 | 0 |
| Another_Unresponsive_{—} | Unresponsive | 3 | 15:29:00 | 4 | 5 |
| Server | | | | | |

The fields in each row of the target table are updated as follows. Initially, all targets are presumed responsive, the time of the first unacknowledged call is negative, and the Number of Unacknowledged Calls for each target is zero.

The total number of calls in transition and the corresponding number for the target are incremented with the first SIP INVITE message, and decremented when the call becomes active or is cancelled.

The total number of active calls and the corresponding number for the target are incremented when setup is complete and decremented when the call is taken down.

The first time a SIP invite to a target times out after a period of responsiveness, the current time is recorded in the “Time of first unacknowledged call” field, and the “Number of Unacknowledged Calls” is incremented.

If a call is acknowledged, the target's state is marked Responsive, the time of the first timeout is set to −1, and the number of unacknowledged calls is set to zero.

If, after a certain time, no calls to a target have been acknowledged, the target is declared down, and all calls to it are rejected until the target is declared to be Responsive, e.g., by the network management system.

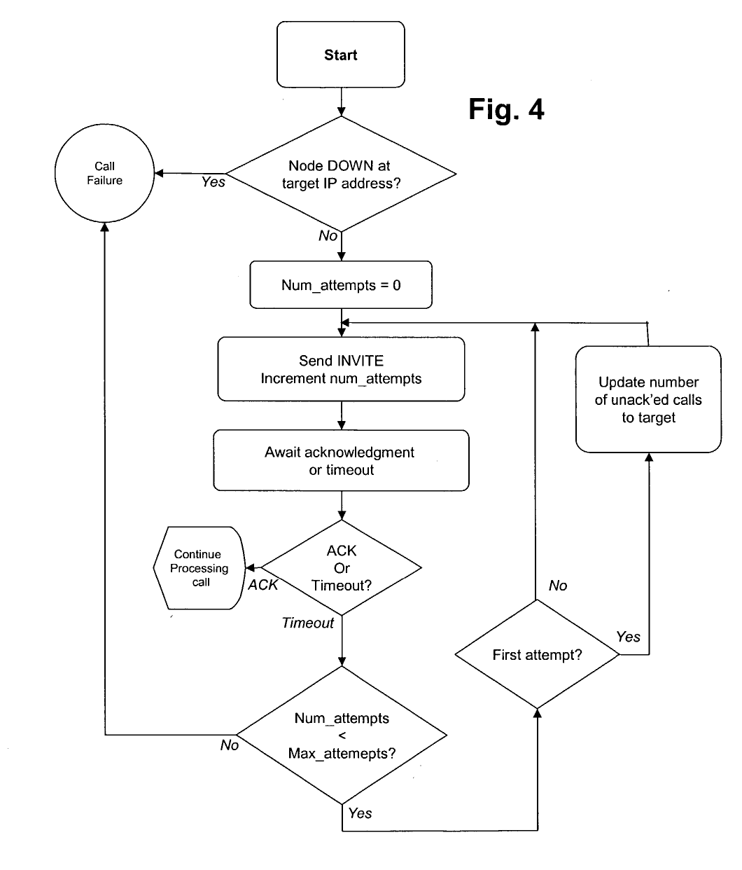

FIG. 4 contains a flowchart demonstrating a possible implementation of the system in connection with accumulating the number of retransmission attempts and comparing the number to a threshold that can be adjusted as discussed hereinabove.

Discrete event simulations were undertaken to determine the reduction in buffer occupancy and timeout processing that could be achieved by implementing the proposed mechanism. A single Poisson stream of calls was simulated, intended for a particular target. The SIP INVITE packets were sent to the target on a unique path. The target acknowledges messages, provided that it is up and running. In one simulation run, calls were attempted up to six times at time intervals specified in the SIP standard, while in another, the number of attempts per call was restricted to two if buffer occupancy exceeded a certain threshold (T1a=52) for more than T=2 seconds, and the number of unacknowledged calls T2a was 1 or greater. The round trip time was modeled as 7.5 msec. In both simulation runs, calls were generated at a rate of 139/sec for 80 seconds of simulated time. The target destination was rendered unresponsive after 10 seconds and restored 40 seconds after that.

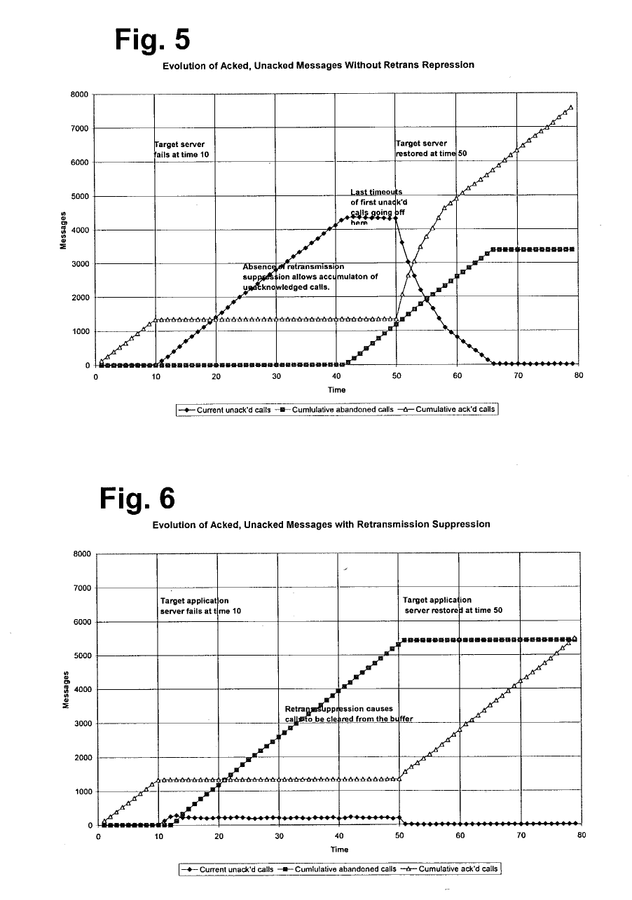

The results are shown as graphs in FIGS. 5 and 6. These figures compare the number of messages (Y axis) over time (X axis) without retransmission suppression (FIG. 5) versus with transmission suppression according to the invention (FIG. 6). The respective traces represent the number of currently unacknowledged calls (line with diamond dots), cumulative number of abandoned calls (square dots) and the cumulative number of acknowledged calls (triangle dots). The number of currently unacknowledged calls is the indicator of backlog.

The reduction in the number of reattempts permitted under congestion or failure conditions was intended to reduce the processing overhead due to timeouts and to reduce the memory occupancy due to calls making reattempts (unacknowledged calls). Both these goals are achieved. The mechanism of the invention therefore is shown to prevent needless overload when a target fails, thus freeing the switch to handle calls addressing other targets.

According to different failure modes, a target node could suddenly assume an Unresponsive state, or the target node might merely become less responsive than it was. Tests and simulation suggest that retransmission suppression in an SIP messaging environment takes hold within a second or two of the time that the target node begins to fail send acknowledgements. Over the 40 seconds that the target was unresponsive, the suppression of retransmissions reduced the number of timeouts by nearly two thirds, while reducing the peak number of unacknowledged calls (and hence the peak buffer size) by more than 90%. These figures reflect the worst case scenarios of a node that suddenly becomes Unresponsive.

The invention is disclosed herein in connection with certain applications, specifically systems operated according to the SIP protocol and having the attributes discussed above. It should be appreciated that the invention is not limited to the exemplary embodiments and can be applied to additional embodiments and situations as well. Reference should be made to the appended claims rather than the foregoing discussion of proposed embodiments in order to assess the scope of the invention in which exclusive rights are claimed.

What is claimed is:

1. A telecommunications system having a plurality of target nodes addressable through communications paths proceeding through proximate switches wherein at least a subset of the target nodes are operable normally to acknowledge messages to an associated proximate switch after receiving a message from said proximate switch, the system comprising:
means for assessing an extent to which a target node is unresponsive by determining at least one of a time from sending a message to a current time, and a number of messages awaiting acknowledgement messages;
wherein the proximate switch is autonomously operable to attempt a further message containing at least one of a retransmission and a status inquiry, to the target node, with respect to at least a subset of the messages awaiting acknowledgement messages; and,
wherein the proximate switch is autonomously operable to automatically reduce at least one of a frequency and a maximum number of attempts to send said further message when the target node is determined to be unresponsive.

2. The system of claim 1, wherein the means for assessing said extent to which the target node is unresponsive comprises a target table associated with the proximate switch, the target table having at least one entry that is incremented according to at least one of said time from sending the message and a count of pending said retry attempts.

3. The system of claim 2, wherein said one of the frequency and the maximum number of attempts is reduced from a predetermined nominal number to a lower number when the target node is determined to be unresponsive.

4. The system of claim 2, wherein said one of the frequency and the maximum number of attempts is reduced when the entry exceeds a predetermined threshold.

5. The system of claim 4, wherein a threshold of at least one of a number of unacknowledged calls to a target and a total permitted number of active calls is variable.

6. The system of claim 4, wherein a minimum time T is variable, said time T being from an occurrence of an unacknowledged call until reduction of said one of the frequency and the maximum number of attempts is reduced.

7. The system of claim 2, wherein said one of the frequency and the maximum number of attempts is reduced in relation to an extent to which the target node is determined to be unresponsive.

8. The system of claim 1, wherein a plurality of said target nodes are coupled to the proximate switch, and wherein the proximate switch separately monitors a Responsive/Unresponsive state for each of said target nodes coupled thereto.

9. The system of claim 8, wherein at least some of the target nodes are addressable through a plurality of said proximate switches, and wherein each said proximate switch determines the Responsive/Unresponsive state of each of said target nodes coupled thereto.

10. The system of claim 2, wherein the telecommunications system operates according to a Session Initiation Protocol standard and wherein at least certain of said messages comprise INVITE messages.

11. The system of claim 10, wherein the proximate switch reduces a maximum number of retry attempts from a higher maximum number during a Responsive state of each said target node to a lower maximum number during an Unresponsive state of said target node.

12. A method for reducing congestion in a telecommunications system having a plurality of target nodes addressable through communications paths proceeding through proximate switches wherein at least a subset of the target nodes are operable normally to acknowledge messages to an associated proximate switch after receiving a message from said proximate switch, comprising the steps of:
assessing an extent to which a target node is unresponsive by determining at least one of a time from sending a message to a current time, and a number of retry attempts, and maintaining a measure of said extent.

13. The method for reducing congestion of claim 12, further comprising comparing the extent to a threshold to determine a failure condition of the target node.

14. The method for reducing congestion of claim 12, further comprising reducing a number of permitted retry attempts upon occurrence of the failure condition.

15. The method for reducing congestion of claim 12, wherein the measure comprises a measure of times from sending the message to the current time.

16. The method for reducing congestion of claim 12, wherein the measure comprises a count of retry attempts pending without acknowledgement from the target node.
